(19) United States
(12) Patent Application Publication
(10) Pub. No.: US 2024/0010572 A1
(43) Pub. Date: Jan. 11, 2024

(54) MANUFACTURING COMPOSITE ELECTROCERAMICS USING WASTE ELECTROCERAMICS

(71) Applicant: OULUN YLIOPISTO, Oulu (FI)

(72) Inventors: Niklas ILONEN, OULU (FI); Heli JANTUNEN, OULU (FI); Jari JUUTI, OULU (FI); Mikko NELO, OULU (FI); Tuomo SIPONKOSKI, OULU (FI)

(21) Appl. No.: 18/257,866

(22) PCT Filed: Dec. 15, 2021
(86) PCT No.: PCT/FI2021/050878

§ 371 Date: Jun. 15, 2023

(30) Foreign Application Priority Data
Dec. 16, 2020 (FI) 20206310

(51) Int. Cl. C04B 35/622; C04B 35/626; C04B 35/64; C04B 35/624

(52) U.S. Cl. CPC C04B 35/62204; C04B 35/6262; C04B 35/6264; C04B 35/62655; C04B 35/64; C04B 35/624; C04B 2235/3256; C04B 2235/444; C04B 2235/48; C04B 2235/5436; C04B 2235/604; C04B 2235/606; C04B 2235/656; B28B 3/02

(57) ABSTRACT

A method for manufacturing composite electroceramics comprises obtaining sintered electroceramic waste material. The waste material is grinded to obtain first ceramic powder having a particle size of 10-400 micron. The first ceramic powder is mixed with NaCl, Li₂MoO₄ or other ceramic powder having a particle size of 0.5-20 micron, in a ratio of 60-90 vol-% said first ceramic powder and 10-40 vol-% NaCl, Li₂MoO₄ or other ceramic powder. The obtained ceramic powder mixture is mixed with aqueous solution of NaCl, Li₂MoO₄ or said other ceramic, in a ratio of 70-90 wt-% the ceramic powder mixture, and 10-30 wt-% the aqueous solution. The obtained homogeneous mass is compressed in a mould for 2-10 min in room temperature and in a pressure of 100-400 MPa. The compressed homogeneous mass is removed from the mould, thereby obtaining electroceramic composite material. Alternatively to the use of the water soluble salt an organometallic precursor compound can be used.

### FIELD OF THE INVENTION

The invention relates to composite electroceramics, and particularly to a method for manufacturing composite electroceramics.

### BACKGROUND ART

Ceramic composite materials are used in a wide range of industries, including mining, aerospace, medicine, refinery, food and chemical industries, packaging science, electronics, industrial and transmission electricity, and guided lightwave transmission. Ceramic composite materials may be used for the manufacture of electronic components. Electronic components may be active components such as semiconductors or power sources, passive components such as resistors or capacitors, actuators such as piezoelectric actuators, or optoelectronic components such as optical switches and/or attenuators. In composite electroceramics manufacturing techniques, aqueous solution of lithium molybdate (LMO, Li₂MoO₄) powder or the like has recently been used as a binder between particles in contrast to conventional thermally driven sintering or melting assisted mechanism.

An amount of electronic waste is huge worldwide, it is estimated to be more than 40 million ton per year in total. Of this, small electronics accounts for about 4 million ton, of which, for example, ceramic components of mobile phones account for about 16%. Today, only about 20% of the electronic waste is recycled in a controlled way.

### SUMMARY

The following presents a simplified summary of features disclosed herein to provide a basic understanding of some exemplary aspects of the invention. This summary is not an extensive overview of the invention. It is not intended to identify key/critical elements of the invention or to delineate the scope of the invention. Its sole purpose is to present some concepts disclosed herein in a simplified form as a prelude to a more detailed description.

According to an aspect, there is provided the subject matter of the independent claims. Embodiments are defined in the dependent claims.

One or more examples of implementations are set forth in more detail in the description below. Other features will be apparent from the description, and from the claims.

### BRIEF DESCRIPTION OF THE DRAWINGS

In the following the invention will be described in greater detail by means of preferred embodiments with reference to the attached drawings, in which

FIGS. 1, 3 and 5 show relative permittivity (εr) values measured at 1 MHz for electroceramic composite materials prepared in accordance with an exemplary embodiment;

FIGS. 2, 4 and 6 show dielectric loss tangent (tan D) values measured at 1 MHz for electroceramic composite materials prepared in accordance with an exemplary embodiment;

FIG. 7 illustrates schematic microstructure of sintered electroceramic waste material from the production of electroceramic components;

FIGS. 8, 9 and 10 illustrate the schematic microstructure of electroceramic composites manufactured according an exemplary embodiment of the present invention.

### DETAILED DESCRIPTION OF EMBODIMENTS

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments. Furthermore, words “comprising”, “containing” and “including” should be understood as not limiting the described embodiments to consist of only those features that have been mentioned and such embodiments may contain also features/structures that have not been specifically mentioned.

Ceramic powder materials may be used in composite materials in which ceramic particles are bonded together by using polymer or glass having a low melting temperature. The ceramic content of such polymer-ceramic composites remains quite low (below 50 vol-%), which significantly impairs the electrical performance of the final product. Ceramic composites may also be prepared by sintering at a high temperature of 750-1700° C. where different thermal expansion coefficients, sintering shrinkages and diffusion mechanisms cause problems, generating undesired material phases.

Therefore, an enhanced method is described herein for manufacturing composite electroceramics. The method comprises obtaining sintered electroceramic waste material from the production of electroceramics-based electronic components. The sintered electroceramic waste material is grinded to obtain first ceramic powder having a particle size of 10-400 μm, preferably 63-180 μm. The first ceramic powder is mixed with NaCl powder, Li₂MoO₄ powder or powder of other ceramic having a particle size of 0.5-20 μm, preferably below 10 μm, in a volume ratio of 60-90 vol-%, preferably 90 vol-%, said first ceramic powder and 10-40 vol-%, preferably 10 vol-%, said NaCl powder, Li₂MoO₄ powder or powder of other ceramic, thereby obtaining a ceramic powder mixture. The obtained ceramic powder mixture is mixed with aqueous solution of NaCl, aqueous solution of Li₂MoO₄ or aqueous solution of said other ceramic, in a weight ratio of 70-90 wt-%, preferably 80 wt-%, the ceramic powder mixture, and 10-30 wt-%, preferably 20 wt-%, the aqueous solution of NaCl, aqueous solution of Li₂MoO₄ or aqueous solution of said other ceramic, thereby obtaining a homogeneous mass. The obtained homogeneous mass is compressed in a mould for 2-10 min, preferably 10 min, in room temperature, and in a pressure of 100-400 MPa, preferably 150 300 MPa, more preferably 250 MPa, thereby obtaining a compressed homogeneous mass. The compressed homogeneous mass is removed from the mould, thereby obtaining electroceramic composite material.

The aqueous solution of NaCl may be saturated aqueous solution of NaCl, the aqueous solution of Li₂MoO₄ may be saturated aqueous solution of Li₂MoO₄, and/or the aqueous solution of said other ceramic may be saturated aqueous solution of said other ceramic. Alternatively, the aqueous solution of NaCl may be non-saturated or almost saturated aqueous solution of NaCl, the aqueous solution of Li₂MoO₄ may be non-saturated or almost saturated aqueous solution of Li₂MoO₄, and/or the aqueous solution of said other ceramic may be non-saturated or almost saturated aqueous solution of said other ceramic.

The obtained electroceramic composite material may be dried in a temperature of 10-150° C., preferably 110° C., for 0.3-48 hours, preferably 10-48 hours, to remove water from the material. The drying may be carried out in the mould during and/or after the compressing, in a desiccator, in an oven, and/or in room air.

Additionally, a method is described herein for manufacturing composite electroceramics, the method comprising obtaining sintered electroceramic waste material from the production of electroceramics-based electronic components. The sintered electroceramic waste material is grinded to obtain ceramic powder having a particle size of 10-400 μm, preferably 63-180 μm. The obtained ceramic powder is mixed with at least one organometallic precursor compound, in a weight ratio of 70-90 wt-%, preferably 80 wt-%, the ceramic powder, and 10-30 wt-%, preferably 20 wt-%, at least one organometallic precursor compound, thereby obtaining a homogeneous mass. The homogeneous mass is compressed in a mould for 10-60 min, preferably 30-60 min, in a temperature of 80-200° C., preferably 160° C., and in a pressure of 100-400 MPa, preferably 150-300 MPa, more preferably 250 MPa, to remove solvent liquid from the homogeneous mass, thereby obtaining a compressed homogeneous mass. The compressed homogeneous mass contained in the mould is further compressed for 10-60 min, preferably 30-60 min, in a temperature of 250-400° C., preferably 350° C., and in a pressure of 100-400 MPa, preferably 150-300 MPa, more preferably 250 MPa, allowing the organometallic precursor compound to react to form metal oxide(s) in the compressed homogeneous mass. Thereafter the compressed homogeneous mass contained in the mould is cooled to a temperature of below 100° C. The compressed homogeneous mass is removed from the mould, thereby obtaining electroceramic composite material.

The compressed homogeneous mass contained in the mould may be cooled to the temperature of below 100° C., e.g. 80° C. or below, e.g. for at least 30 min, while allowing the pressure in the mould to decrease, before removing compressed homogeneous mass from the mould.

The at least one organometallic precursor compound may be gel-like organometallic precursor compound capable of forming metal oxide(s) or other organometallic compound capable of forming metal oxide(s), or a mixture thereof capable of forming metal oxide(s), and/or a gel-like sol-gel reaction product capable of forming metal oxide(s) under the influence of heat.

The metal oxide may be TiO₂, PZT, BaTiO₃, BaₓSr₁₋ₓTiO₃, Al₂O₃, KNBNNO, ferrite material, titanate material, niobate material, and/or perovskite material.

The gel-like organometallic precursor compound capable of forming metal oxide(s) or the other organometallic compound capable of forming metal oxide(s), or the mixture thereof, may be selected such that metal oxide(s) to be formed during said further compressing in the compressed homogeneous mass contained in the mould correspond(s) to an elemental composition of the ceramic powder obtained from the sintered electroceramic waste material.

Said ceramic powder, ceramic powder mixture, NaCl powder, Li₂MoO₄ powder or powder of other ceramic, and/or first ceramic powder may have a multimodal particle size, having particles with two or more different particle sizes.

80-90 vol %, preferably 85-90 vol-%, of the content of the produced electroceramic composite material may originate from the sintered electroceramic waste material, the rest 10-20 vol %, preferably 10-15 vol-%, being NaCl, Li₂MoO₄ or other ceramic, or metal oxide.

The sintered electroceramic waste material obtained from the production of electroceramic components may be dielectric, ferroelectric, ferromagnetic, paraelectric, paramagnetic, piezoelectric and/or pyroelectric material, and/or the sintered electroceramic waste material may be obtained from the production of a resistors, conductors, capacitors, coils, sensors, actuators, high frequency passive devices, energy storage components, energy harvesting components, tuning elements, transformers, optical switches, antennas, optical attenuators, batteries, light emitting diodes, active components, integrated circuits, and/or electrical circuit boards.

Said other ceramic may be one or more of Na₂Mo₂O₇, K₂Mo₂O₇, (LiBi)_{0.5}MoO₄, KH₂PO₄, Li₂WO₄, Mg₂P₂O₇, V₂O₅, LiMgPO₄, and/or any other water-soluble ceramic.

Electroceramic composite produced by the method may be such that waste material based ceramic content of the electroceramic composite is 80-90 vol-%, preferably 85-90 vol-%, said waste material based ceramic content originating from the sintered electroceramic waste material from the production of electroceramic components, and NaCl, Li₂MoO₄ or other ceramic or metal oxide based binder content of the electroceramic composite is 10-20 vol-%, preferably 10-15 vol-%, said binder content forming a binder phase in the electroceramic composite, binding the waste material based ceramic content of the electroceramic composite. The electroceramic composite may be dielectric, ferroelectric, ferromagnetic, paraelectric, paramagnetic, piezoelectric and/or pyroelectric composite. Electronic component is also disclosed, comprising said electroceramic composite. The electroceramic composite may be used in the manufacture of an electronic component and/or optoelectronic component. The electronic component may be a resistor, conductor, capacitor, coil, sensor, actuator, high frequency passive device, energy storage component, energy harvesting component, tuning element, transformer, optical switch, antenna, optical attenuator, battery, light emitting diode, active component, integrated circuit, and/or electrical interconnection.

The present invention utilizes recycled ceramic material to produce electroceramic composite material. By using ceramic reject material generated in connection with the manufacture of electronic components as the ceramic material in the composite, instead of virgin material, the costs and energy consumption of the manufacturing method of the composite are decreased.

The invention discloses a manufacturing method in which discarded electronic component waste generated in connection with industrial manufacture of electroceramics, e.g. due to incorrect shape or fractures in the component, is utilized to produce ceramic composite for similar or other electroceramics purposes. In the method, the discarded ceramic items or components are sorted based on material type and/or application, and if needed crushed to a desired particle size, after which the obtained powder is used directly in the manufacture or coated with an inorganic substance such as LMO or other water-soluble metal oxide or NaCl. The resulting ceramic powder material is bonded together with a ceramic or salt-forming solution and the formed homogeneous mass is compression molded. The method enables obtaining ceramic composites having exceptionally good electrical performance as a composite.

The ceramic-forming binder may be an aqueous solution of a water-soluble metal oxide (e.g. lithium molybdate, Li₂MoO₄, LMO) or an aqueous solution of a water-soluble salt (e.g. NaCl), or alternatively a precursor of an organometallic compound which, by using elevated pressure and/or heating, forms metal oxide (s). The binder is added in liquid form to the ceramic powder material where its function is to form a bond between the particles of the ceramic powder material, by means of elevated pressure and/or heating. The temperature range used is exceptionally low, preferably room temperature 20-25° C., or in case of a precursor 250 400° C.

The method involves grinding electroceramic items or components damaged during sintering in the electronics industry, and mixing the obtained ceramic powder material together with LMO powder. Binder may be added to the mixture such that a homogeneous mass is formed, and compression molding the homogenous mass into ceramic composite having a density and electrical performance suitable for electroceramic composite material. The method may also use two or more different ceramic materials, and it may be optimized for bonding different types of ceramic materials. Instead of or in addition to LMO, other water-soluble ceramic or metal oxide or water-soluble salt such as NaCl, may be used.

The present invention utilizes reject material from the electronics components for the production of electroceramic materials. Various ceramic materials are an important part of the components used in electronics. The amount of waste generated in the sintering process or electronic components is generally not known, but even a few percent of the production volume means a significant economic loss on an annual basis. Utilization of reject materials is also desired due to tightening environmental regulations and increasing waste treatment costs. At present, there is no known straightforward, cost-effective and energy-efficient method of recycling ceramic waste, but it usually ends up being disposed of, for example, as a landfill, even though the electroceramic components is very highly processed material that has required a considerable amount of energy in the production.

The present invention makes it possible to produce high-performance ceramic composites with very low energy consumption, from a substantially cost free or even negative cost (waste treatment costs are avoided) reject material and a small amount of binder, at a very reasonable purchase price. In addition, for example, in the case of LMO, the prepared electroceramic composite is further recyclable.

The present invention makes it possible to manufacture components from ceramic waste in the electronics industry with very low energy consumption. In the present invention, ceramic items that have been discarded in the manufacture of electroceramics, e.g. broken or incorrectly shaped pieces or pieces unsuitable for specifications, may be utilized completely and do not become waste. Thus, the utilization of material and energy becomes more efficient and the increase in productivity is significant when difficult-to-recycle waste is turned into commercial electronic components.

Electronics industry uses large quantities of sintered electroceramics. In the manufacture of electroceramics, a certain amount of reject material is generated, for example, due to fractures caused by sintering or unwanted dimensional changes (sintering shrinkage). The exact share of rejects in production volumes is most often a trade secret, but especially when manufacturing challenging structures, the share of rejects is expected to be significant. This reject material needs to be disposed properly, which incurs additional costs for the manufacturer, in addition to material loss. As said above, currently there is no commercially significant reuse of this reject material. The present invention provides a manufacturing method which utilizes as a raw material the electroceramic reject material generated in the sintering process, wherein electroceramic composite materials with excellent performance are produced at low temperatures.

The invention utilizes a method for manufacturing ceramic composites, in which a ceramic powder with a precisely controlled particle size distribution is mixed with a metal oxide forming solution and compressed into a ceramic composite. The ceramic-forming solution may be either an aqueous solution of a water-soluble metal oxide (e.g. LMO) or, alternatively, a precursor of an organometallic compound which, when heated under pressure, reacts to bind the particles together. The metal oxide fills the space between the particles of the filler (electroceramic waste powder), the particle size of which is precisely controlled. Careful selection of the particle size distribution of the filler allows a very small need of the binder phase, whereby the filler phase constitutes 80-90 vol-%, preferably 85-90 vol-%, of the total volume of the manufactured composite item, and the electrical properties of the manufactured composite items are considerably improved.

The present invention enables utilizing of electroceramic materials thereby providing low raw material costs, excellent electrical performance of the prepared composite. The invention may be utilized in the ceramics component industry to enhance materials recycling.

The manufacturing process significantly improves the electrical performance of composite by increasing the proportion of functional ceramic of the composite to 80-90 vol-%, preferably 85-90 vol-%.

The preparation of the ceramic composite according to the present invention proceeds, for example, as follows.

The method comprises acquiring electroceramic material generated in the manufacture of electroceramics, rejected after sintering, which has not met the product requirements. The ceramic material may be, for example, a high or low permittivity dielectric material, a piezoelectric or pyroelectric material, or another ceramic material used as an electroceramic. Primarily, it is intended to use only one type of rejected material in each composite to facilitate selection of the appropriate binder phase and compression parameters. However, the low manufacturing temperature also allows several different types of electroceramics to be combined into the composite, for example, with several different properties in different layers.

The acquired ceramic material is crushed, if needed, and screened to the desired particle size, for example, 10-400 μm, preferably 63-180 μm (typical ceramic waste powder crystal size is 2 μm, i.e. 1 particle contains several crystals, i.e. it differentiates by microstructure) and, if necessary, the powder is coated with inorganic coating (such as LMO) for better processing density.

A binder is added, which may be e.g. LMO (a) or an organometallic compound precursor gel (b). In case (a) an aqueous solution of LMO is used, while in case (b) a precursor gel capable of forming metal oxide such as a titanium oxide, is used. The substances are mixed to obtain a homogeneous mass, and the homogeneous mass is evenly layered in a compression mold. The homogeneous mass is compressed (a) in room temperature or (b) in elevated temperature 80-200° C., preferably 160° C., and in a pressure of 100-400 MPa, preferably 150-300 MPa, more preferably 250 MPa. In case (a) the compression is carried for 2-10 min, preferably 10 min. In case (b), the compression is carried for 10-60 min, preferably 30-60 min, after the compressed homogeneous mass is further compressed in the mould for 10-60 min, preferably 30-60 min, in a temperature of 250-400° C., preferably 350° C., and in a pressure of 100-400 MPa, preferably 150-300 MPa, more preferably 250 MPa, allowing the organometallic precursor compound to react to form metal oxide(s) in the compressed homogeneous mass.

Next, in case (a) the compressed homogeneous mass is removed from the mold, and water is allowed to evaporate. This also happens at room temperature, but drying may be accelerated in an oven (e.g. 110° C.).

In case (b) the mold may be cooled to below 100° C. for at least 30 minutes, keeping the pressure stable. After the mold has cooled, the pressure is lowered and the prepared composite is removed from the mold, thereby obtaining electroceramic composite material. The compressed homogeneous mass contained in the mould may be cooled to the temperature of below 100° C., preferably 80° C. or below, e.g. for at least 30 min, while allowing the pressure in the mould to decrease.

After that the obtained electroceramic composite is ready for electrode fabrication or other electronic component making and measurements.

In the pre-treatment of waste powder, different types of ceramic particles may be bonded together (or other powders such as conductive metal powders) to obtain composites with several different electrical properties simultaneously.

The binder selection may be optimized with respect to the material to be bonded, by using a binder that wets the material particularly well.

The binder gel to be used may be selected so that it forms the same compound as the filler particles of the composite.

The particle size of the ceramic object may also be varied in a range other than 63-180 μm in order to make its level of filling as large as possible, e.g. using three particle sizes.

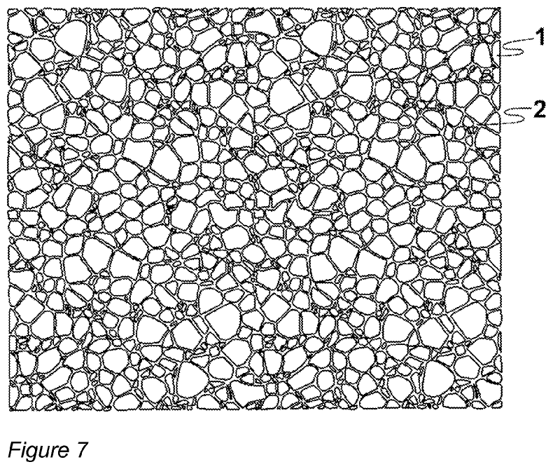

FIG. 7 illustrates schematic microstructure of sintered electroceramic waste material from the production of electroceramic components (not in scale), showing electroceramic particles 1 and grain boundaries 2 of the electroceramic particles 1.

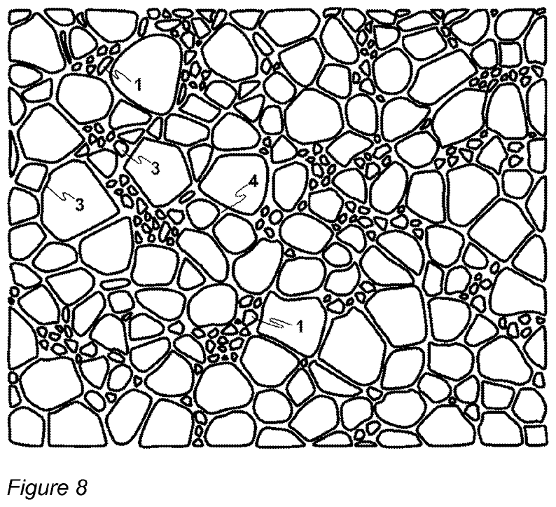

FIG. 8 illustrates schematic microstructure of electroceramic composite manufactured according an exemplary embodiment of the present invention, showing electroceramic waste material distributed as small electroceramic particles 1 within the ceramic matrix material 3 (first ceramic powder), and grain boundary areas 4 of the ceramic composite.

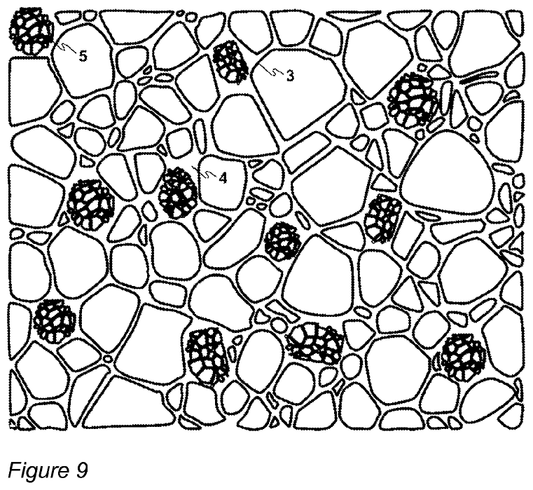

FIG. 9 illustrates schematic microstructure of electroceramic composite manufactured according an exemplary embodiment of the present invention, showing electroceramic waste material distributed as granules/clusters 5 of particles within the ceramic matrix material 3 (first ceramic powder), and grain boundary areas 4 of the ceramic composite.

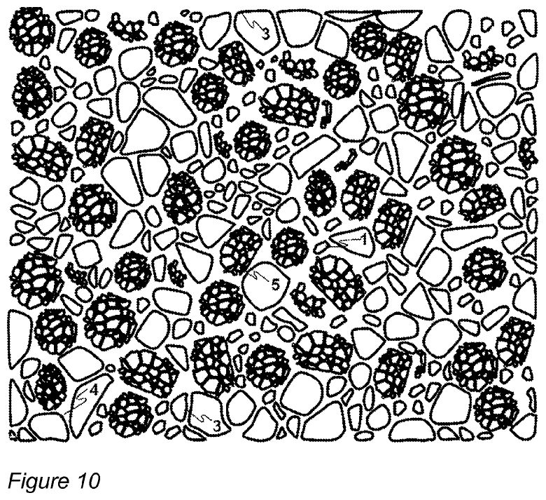

FIG. 10 illustrates schematic microstructure of electroceramic composite manufactured according an exemplary embodiment of the present invention, showing electroceramic waste material distributed as small particles 1 and cluster/granules of electroceramic particles 5, within the ceramic matrix material 3 (first ceramic powder), and grain boundary areas 4 of the ceramic composite.

### Example 1

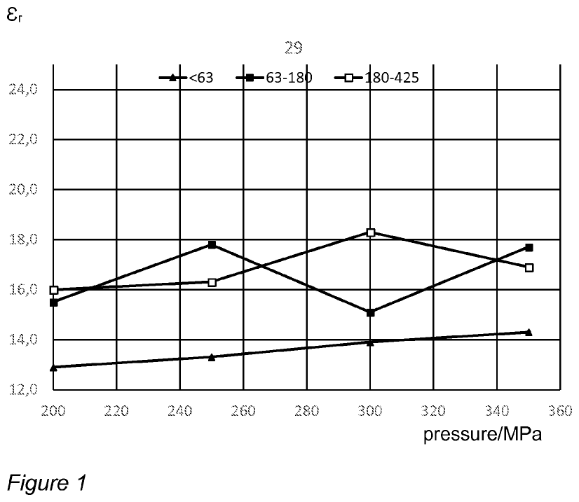

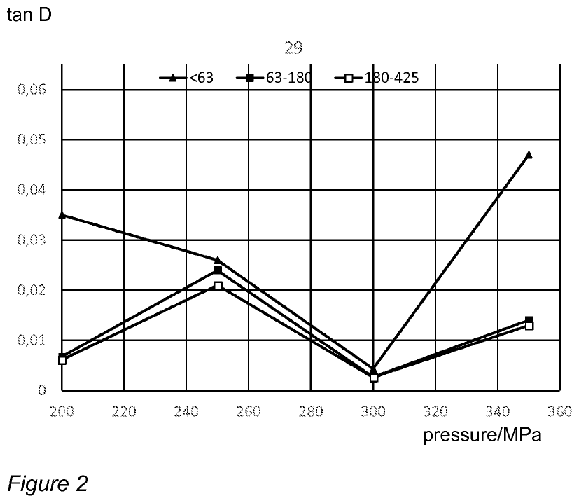

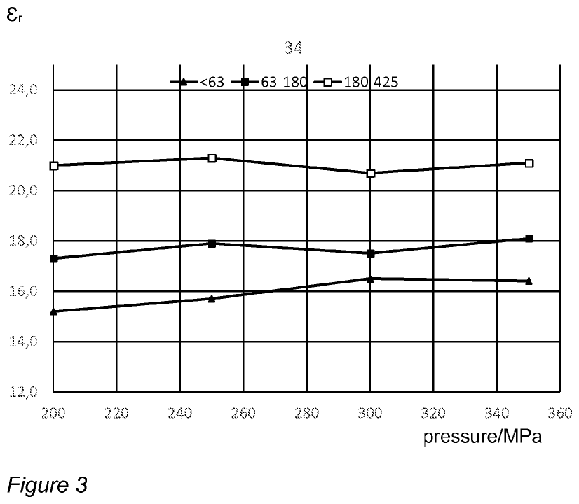

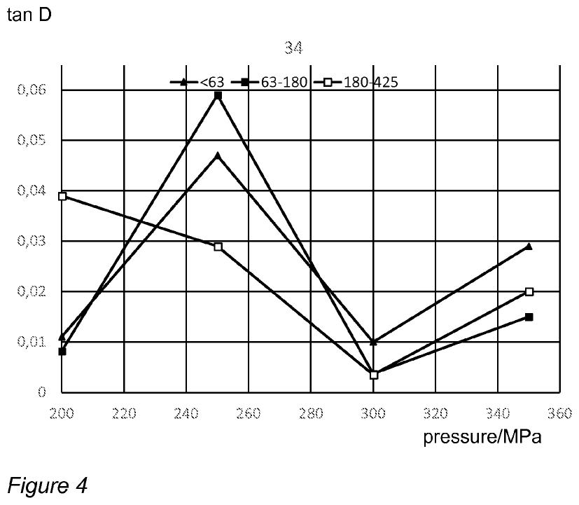

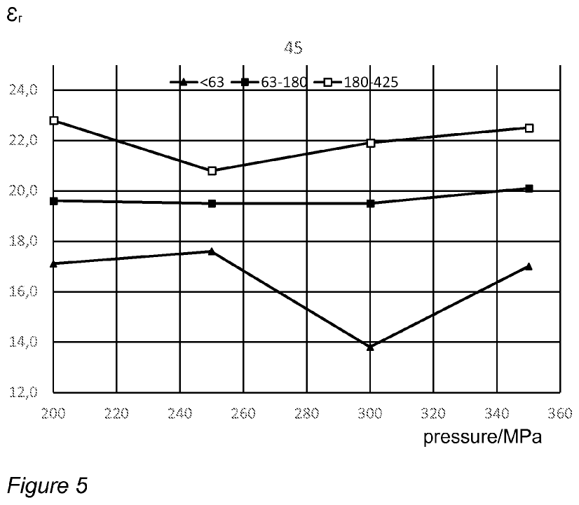

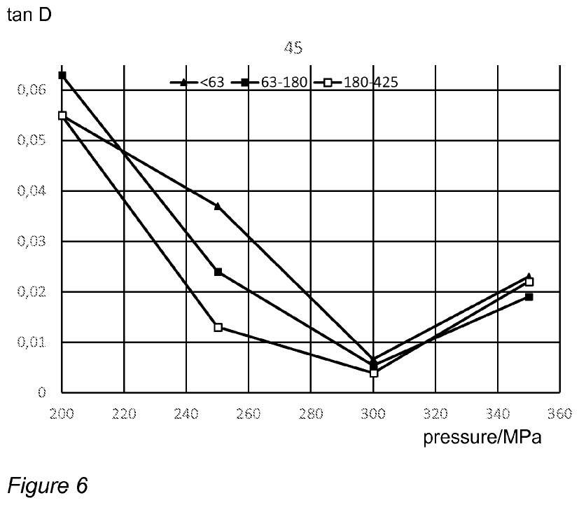

Experiments with three different recycled ceramic materials and lithium molybdate were performed. A dense sample of the materials were compressed. There was a variation in the density of the final product between the materials, with some of the materials compressing and bonding together better than others. By optimizing the binder used and its amount as well as the compression parameters, the density and thus the material properties could be further influenced. The samples were prepared by mixing 10 wt-% (0.10 g) LMO powder having a particle size below 20 μm, with 90 wt-% (0.90 g) recycled electroceramics from the production of electroceramic components. Three different particle sizes of the recycled ceramics (<63 μm, 63-180 μm, 180-425 μm) and three different sample types (relative permittivity of the recycled electroceramics εr=29, εr=34, εr=45) were used. 0.2 ml of saturated aqueous solution of LMO was added to the powder mixture. The samples were homogenized in a mold using an ultrasonic mixer. A compression for 9-10 min (or 3-5 min) was applied in the mold at selected pressure. A mold size of 10 mm in diameter was used. The results are shown in Table 1 and in FIGS. 1-6 as averages for two samples, showing the relative permittivity (εr) and the dielectric loss tangent (tan D) measured at 1 MHz frequency, for the prepared electroceramic composite materials. Densities calculated from the dimensions of the compression molded pieces (average of three samples) were compared to that of the bulk density of ceramic filler.

TABLE 1

| Raw | | | | | | |
|---|---|---|---|---|---|---|
| material | Particle | Pressure | Density | εr | Tan D | |
| εr | size, μm | MPa | % bulk | 1 MHz | 1 MHz | Compression |
| 29 | <63 | 200 | 88.4 | 12.9 | 0.035 | 9-10 min, 15.5 kN |
| | 63-180 | | 95.8 | 15.5 | 0.0067 | |
| | 180-425 | | 98.5 | 16.0 | 0.0061 | |
| 34 | <63 | | 79.7 | 15.2 | 0.011 | |
| | 63-180 | | 82.5 | 17.3 | 0.0081 | |
| | 180-425 | | 85.1 | 21.0 | 0.039 | |
| 45 | <63 | | 72.6 | 17.1 | 0.055 | |
| | 63-180 | | 72.8 | 19.6 | 0.063 | |
| | 180-425 | | 75.0 | 22.8 | 0.055 | |
| 29 | <63 | 250 | 87.8 | 13.3 | 0.026 | εr 29, 34: |
| | 63-180 | | 95.9 | 17.8 | 0.024 | 9-10 min, 20 kN |
| | 180-425 | | >99.9 | 16.3 | 0.021 | εr 45: 3-5 min, 20 kN |
| 34 | <63 | | 79.4 | 15.7 | 0.047 | |
| | 63-180 | | 83.3 | 17.9 | 0.059 | |
| | 180-425 | | 86.8 | 21.3 | 0.029 | |
| 45 | <63 | | 74.2 | 17.6 | 0.037 | |
| | 63-180 | | 76.1 | 19.5 | 0.024 | |
| | 180-425 | | 75.6 | 20.8 | 0.013 | |
| 29 | <63 | 300 | 90.5 | 13.9 | 0.0043 | 9-10 min, 23.5 kN |
| | 63-180 | | 99.0 | 15.1 | 0.0027 | |
| | 180-425 | | >99.9 | 18.3 | 0.0026 | |
| 34 | <63 | | 80.2 | 16.5 | 0.01 | |
| | 63-180 | | 82.2 | 17.5 | 0.0037 | |
| | 180-425 | | 88.9 | 20.7 | 0.0035 | |
| 45 | <63 | | 74.9 | 13.8 | 0.0066 | |
| | 63-180 | | 75.8 | 19.5 | 0.0054 | |
| | 180-425 | | 77.8 | 21.9 | 0.0039 | |
| 29 | <63 | 350 | 90.8 | 14.3 | 0.047 | 9-10 min, 27.5 kN |
| | 63-180 | | 99.3 | 17.7 | 0.014 | |
| | 180-425 | | >99.9 | 16.9 | 0.013 | |
| 34 | <63 | | 81.8 | 16.4 | 0.029 | |
| | 63-180 | | 87.0 | 18.1 | 0.015 | |
| | 180-425 | | 89.1 | 21.1 | 0.02 | |
| 45 | <63 | | 75.2 | 17.0 | 0.023 | |
| | 63-180 | | 78.1 | 20.1 | 0.019 | |
| | 180-425 | | 78.3 | 22.5 | 0.022 | |

It will be obvious to a person skilled in the art that, as the technology advances, the inventive concept can be implemented in various ways. The invention and its embodiments are not limited to the examples described above but may vary within the scope of the claims.

1. A method for manufacturing composite electroceramics, the method comprising
obtaining sintered electroceramic waste material from the production of electroceramic components;
grinding the sintered electroceramic waste material to obtain first ceramic powder having a particle size of 10-400 μm, preferably 63-180 μm;
mixing the first ceramic powder with NaCl powder, Li₂MoO₄ powder or powder of other ceramic having a particle size of 0.5-20 μm, preferably below 10 μm, in a volume ratio of 60-90 vol-%, preferably 90 vol-%, said first ceramic powder and 10-40 vol-%, preferably 10 vol-%, said NaCl powder, Li₂MoO₄ powder or powder of other ceramic, thereby obtaining a ceramic powder mixture;
mixing the obtained ceramic powder mixture with aqueous solution of NaCl, aqueous solution of Li₂MoO₄ or aqueous solution of said other ceramic, in a weight ratio of 70-90 wt-%, preferably 80 wt-%, the ceramic powder mixture, and 10-30 wt-%, preferably 20 wt-%, the aqueous solution of NaCl, aqueous solution of Li₂MoO₄ or aqueous solution of said other ceramic, thereby obtaining a homogeneous mass;
compressing the obtained homogeneous mass in a mould for 2-10 min, preferably 10 min, in room temperature, and in a pressure of 100-400 MPa, preferably 150-300 MPa, more preferably 250 MPa, thereby obtaining a compressed homogeneous mass; and
removing the compressed homogeneous mass from the mould, thereby obtaining electroceramic composite material.

2. A method as claimed in claim 1, the method comprising drying the obtained electroceramic composite material in a temperature of 10-150° C., preferably 110° C., for 0.3-48 hours, preferably 10-48 hours, to remove water from the material,
wherein the drying is carried out in the mould during and/or after the compressing, in a desiccator, in an oven, and/or in room air.

3. A method as claimed in claim 1, wherein
the aqueous solution of NaCl is saturated aqueous solution of NaCl,
the aqueous solution of Li₂MoO₄ is saturated aqueous solution of Li₂MoO₄, and/or
the aqueous solution of said other ceramic is saturated aqueous solution of said other ceramic.

4. A method for manufacturing composite electroceramics, the method comprising
obtaining sintered electroceramic waste material from the production of electroceramic components;
grinding the sintered electroceramic waste material to obtain ceramic powder having a particle size of 10-400 μm, preferably 63-180 μm;
mixing the obtained ceramic powder with at least one organometallic precursor compound, in a weight ratio of 70-90 wt-%, preferably 80 wt-%, the ceramic powder and 10-30 wt-%, preferably 20 wt-%, at least one organometallic precursor compound, thereby obtaining a homogeneous mass;
compressing the homogeneous mass in a mould for 10-60 min, preferably 30-60 min, in a temperature of 80-200° C., preferably 160° C., and in a pressure of 100-400 MPa, preferably 150-300 MPa, more preferably 250 MPa, to remove solvent liquid from the homogeneous mass, thereby obtaining a compressed homogeneous mass;
further compressing the compressed homogeneous mass contained in the mould for 10-60 min, preferably 30-60 min, in a temperature of 250-400° C., preferably 350° C., and in a pressure of 100-400 MPa, preferably 150-300 MPa, more preferably 250 MPa, allowing the organometallic precursor compound to react to form metal oxide(s) in the compressed homogeneous mass; and
thereafter cooling the compressed homogeneous mass contained in the mould to a temperature of below 100° C., and removing the compressed homogeneous mass from the mould, thereby obtaining electroceramic composite material.

5. A method as claimed in claim 4, wherein the at least one organometallic precursor compound is
gel-like organometallic precursor compound capable of forming metal oxide(s) or other organometallic compound capable of forming metal oxide(s), or a mixture thereof capable of forming metal oxide(s), and/or
a gel-like sol-gel reaction product capable of forming metal oxide(s) under the influence of heat.

6. A method as claimed in claim 5, wherein the metal oxide is TiO₂, PZT, BaTiO₃, BaₓSr₁₋ₓTiO₃, Al₂O₃, KNBNNO, ferrite material, titanate material, niobate material, and/or perovskite material.

7. A method as claimed in claim 5, wherein the gel-like organometallic precursor compound capable of forming metal oxide(s) or the other organometallic compound capable of forming metal oxide(s), or the mixture thereof, is selected such that metal oxide(s) to be formed during said further compressing in the compressed homogeneous mass contained in the mould correspond(s) to an elemental composition of the ceramic powder obtained from the sintered electroceramic waste material.

8. A method as claimed in claim 1, wherein said ceramic powder, ceramic powder mixture, NaCl powder, Li₂MoO₄ powder or powder of other ceramic, and/or first ceramic powder has a multimodal particle size, having particles with two or more different particle sizes.

9. A method as claimed in claim 1, wherein
80-90 vol %, preferably 85-90 vol-%, of the content of the electroceramic composite material originates from the sintered electroceramic waste material,
the rest 10-20 vol %, preferably 10-15 vol-%, being NaCl, Li₂MoO₄ or other ceramic, or metal oxide.

10. A method as claimed in claim 1, wherein
the sintered electroceramic waste material obtained from the production of electroceramic components is dielectric, ferroelectric, ferromagnetic, paraelectric, paramagnetic, piezoelectric and/or pyroelectric material, and/or
the sintered electroceramic waste material is obtained from the production of a resistors, conductors, capacitors, coils, sensors, actuators, high frequency passive devices, energy storage components, energy harvesting components, tuning elements, transformers, optical switches, antennas, optical attenuators, batteries, light emitting diodes, active components, integrated circuits, and/or electrical circuit boards.

11. A method as claimed in claim 1, wherein said other ceramic is one or more of Na₂Mo₂O₇, K₂Mo₂O₇, (LiBi)_{0.5}MoO₄, KH₂PO₄, Li₂WO₄, Mg₂P₂O₇, V₂O₅, LiMgPO₄, and/or any other water-soluble ceramic.

12. Electroceramic composite produced by the method as claimed in claim 1, wherein
grinded sintered electroceramic waste material content of the electroceramic composite is 80-90 vol-%, preferably 85-90 vol-%, said grinded sintered electroceramic waste material content originating from the production of electroceramic components, and having a particle size of 10-400 μm, preferably 63-180 μm, and
NaCl, Li₂MoO₄ or other ceramic or metal oxide based binder content of the electroceramic composite is 10-20 vol-%, preferably 10-15 vol-%, said binder content forming a binder phase in the electroceramic composite, binding the grinded sintered electroceramic waste material content of the electroceramic composite.

13. Electroceramic composite as claimed in claim 12, wherein the electroceramic composite is dielectric, ferroelectric, ferromagnetic, paraelectric, paramagnetic, piezoelectric and/or pyroelectric composite.

14. Electronic component comprising the electroceramic composite as claimed in claim 12.

15. Use of the electroceramic composite as claimed in claim 12 in the manufacture of an electronic component and/or optoelectronic component.

16. Electronic component as claimed in claim 12, wherein the electronic component is a resistor, conductor, capacitor, coil, sensor, actuator, high frequency passive device, energy storage component, energy harvesting component, tuning element, transformer, optical switch, antenna, optical attenuator, battery, light emitting diode, active component, integrated circuit, and/or electrical circuit board.

17. A method as claimed in claim 4 wherein said ceramic powder, ceramic powder mixture, NaCl powder, Li₂MoO₄ powder or powder of other ceramic, and/or first ceramic powder has a multimodal particle size, having particles with two or more different particle sizes.

18. A method as claimed in claim 4, wherein
80-90 vol %, preferably 85-90 vol-%, of the content of the electroceramic composite material originates from the sintered electroceramic waste material,
the rest 10-20 vol %, preferably 10-15 vol-%, being NaCl, Li₂MoO₄ or other ceramic, or metal oxide.

19. A method as claimed in claim 4, wherein
the sintered electroceramic waste material obtained from the production of electroceramic components is dielectric, ferroelectric, ferromagnetic, paraelectric, paramagnetic, piezoelectric and/or pyroelectric material, and/or
the sintered electroceramic waste material is obtained from the production of a resistors, conductors, capacitors, coils, sensors, actuators, high frequency passive devices, energy storage components, energy harvesting components, tuning elements, transformers, optical switches, antennas, optical attenuators, batteries, light emitting diodes, active components, integrated circuits, and/or electrical circuit boards.

20. A method as claimed in claim 4, wherein said other ceramic is one or more of Na₂Mo₂O₇, K₂Mo₂O₇, (LiBi)_{0.5}MoO₄, KH₂PO₄, Li₂WO₄, Mg₂P₂O₇, V₂O₅, LiMgPO₄, and/or any other water-soluble ceramic.

21. Electroceramic composite produced by the method as claimed in claim 4, wherein
grinded sintered electroceramic waste material content of the electroceramic composite is 80-90 vol-%, preferably 85-90 vol-%, said grinded sintered electroceramic waste material content originating from the production of electroceramic components, and having a particle size of 10-400 μm, preferably 63-180 μm, and
NaCl, Li₂MoO₄ or other ceramic or metal oxide based binder content of the electroceramic composite is 10-20 vol-%, preferably 10-15 vol-%, said binder content forming a binder phase in the electroceramic composite, binding the grinded sintered electroceramic waste material content of the electroceramic composite.

22. Electroceramic composite as claimed in claim 21, wherein the electroceramic composite is dielectric, ferroelectric, ferromagnetic, paraelectric, paramagnetic, piezoelectric and/or pyroelectric composite.

23. Electronic component comprising the electroceramic composite as claimed in claim 21.

24. Use of the electroceramic composite as claimed in claim 21 in the manufacture of an electronic component and/or optoelectronic component.

25. Electronic component as claimed in claim 23, wherein the electronic component is a resistor, conductor, capacitor, coil, sensor, actuator, high frequency passive device, energy storage component, energy harvesting component, tuning element, transformer, optical switch, antenna, optical attenuator, battery, light emitting diode, active component, integrated circuit, and/or electrical circuit board.

26. The use of claim 24, wherein the electronic component is a resistor, conductor, capacitor, coil, sensor, actuator, high frequency passive device, energy storage component, energy harvesting component, tuning element, transformer, optical switch, antenna, optical attenuator, battery, light emitting diode, active component, integrated circuit, and/or electrical circuit board.
